(19) United States
(12) Patent Application Publication
(10) Pub. No.: US 2026/0162723 A1
(43) Pub. Date: Jun. 11, 2026

(54) SEMICONDUCTOR MEMORY DEVICE

(71) Applicant: Kioxia Corporation, Tokyo (JP)

(72) Inventors: Shunichi SENO, Yokkaichi (JP); Kouji MATSUO, Ama (JP); Yuki NAKATA, Yokkaichi (JP); Fumitaka ARAI, Yokkaichi (JP)

(73) Assignee: Kioxia Corporation, Tokyo (JP)

(21) Appl. No.: 19/298,517

(22) Filed: Aug. 13, 2025

(30) Foreign Application Priority Data
Dec. 9, 2024 (JP) 2024-214554

(51) Int. Cl. G11C 16/04; G11C 5/06; H10B 41/10; H10B 41/27

(52) U.S. Cl. CPC G11C 16/0483; G11C 5/063; H10B 41/10; H10B 41/27

(57) ABSTRACT

A semiconductor memory device comprises: memory block regions; a hook-up region arranged with respect to memory block regions; and a wiring region arranged with memory block regions. Memory block regions each comprise: memory strings; and a first wiring commonly connected to memory strings. The wiring region comprises a second wiring which is commonly connected to the first wirings corresponding to memory block regions. The hook-up region comprises a contact electrode which is electrically connected to the second wiring. A first transistor is provided in a current path between the first wiring and the second wiring.

### CROSS-REFERENCE TO RELATED APPLICATIONS

This application is based upon and claims the benefit of Japanese Patent Application No. 2024-214554, filed on Dec. 9, 2024, the entire contents of which are incorporated herein by reference.

### BACKGROUND

### Field

The present embodiments relate to semiconductor memory devices.

### Description of the Related Art

There is known a semiconductor memory device in which a plurality of memory cells are stacked in a direction intersecting a surface of a substrate.

### BRIEF DESCRIPTION OF THE DRAWINGS

FIG. 1 is a schematic plan view showing a configuration of a part of a semiconductor memory device according to a first embodiment;

FIG. 2 is a circuit diagram showing a configuration of a part of same semiconductor memory device;

FIG. 3 is a schematic plan view showing a configuration of a part of same semiconductor memory device;

FIG. 4 is a schematic plan view showing an enlarged part of FIG. 3;

FIG. 5 is a schematic perspective view including the portion shown in FIG. 4;

FIG. 6 is a schematic cross-sectional view in which the structure shown in FIG. 4 has been cut along the line A-A′ and viewed along a direction of the arrows;

FIG. 7 is a schematic cross-sectional view in which the structure shown in FIG. 4 has been cut along the line B-B′ and viewed along a direction of the arrows;

FIG. 8 is a schematic cross-sectional view in which the structure shown in FIG. 4 has been cut along the line C-C′ and viewed along a direction of the arrows;

FIG. 9 is a schematic plan view showing a configuration of a part of a hook-up region R_{HU};

FIG. 10 is a schematic cross-sectional view in which the structure shown in FIG. 9 has been cut along the line D-D′ and viewed along a direction of the arrows;

FIG. 11 is a schematic cross-sectional view in which the structure shown in FIG. 9 has been cut along the line E-E′ and viewed along a direction of the arrows;

FIG. 12 is a schematic plan view for explaining a modified example of the semiconductor memory device according to the first embodiment;

FIG. 13 is a circuit diagram showing a configuration of a part of a semiconductor memory device according to a second embodiment;

FIG. 14 is a schematic plan view showing a configuration of a part of same semiconductor memory device;

FIG. 15 is a schematic plan view for explaining a method of manufacturing the semiconductor memory devices according to the first and second embodiments;

FIG. 16 is a schematic cross-sectional view for explaining same method of manufacturing;

FIG. 17 is a schematic cross-sectional view for explaining same method of manufacturing;

FIG. 18 is a schematic cross-sectional view for explaining same method of manufacturing;

FIG. 19 is a schematic plan view for explaining same method of manufacturing;

FIG. 20 is a schematic cross-sectional view for explaining same method of manufacturing;

FIG. 21 is a schematic plan view for explaining same method of manufacturing;

FIG. 22 is a schematic cross-sectional view for explaining same method of manufacturing;

FIG. 23 is a schematic plan view for explaining same method of manufacturing;

FIG. 24 is a schematic cross-sectional view for explaining same method of manufacturing;

FIG. 25 is a schematic plan view for explaining same method of manufacturing;

FIG. 26 is a schematic cross-sectional view for explaining same method of manufacturing;

FIG. 27 is a schematic plan view for explaining same method of manufacturing;

FIG. 28 is a schematic cross-sectional view for explaining same method of manufacturing;

FIG. 29 is a schematic plan view for explaining same method of manufacturing;

FIG. 30 is a schematic cross-sectional view for explaining same method of manufacturing;

FIG. 31 is a schematic plan view for explaining same method of manufacturing;

FIG. 32 is a schematic cross-sectional view for explaining same method of manufacturing;

FIG. 33 is a schematic plan view showing a configuration of a part of a semiconductor memory device according to a third embodiment;

FIG. 34 is a schematic plan view showing a configuration of a part of a semiconductor memory device according to a fourth embodiment;

FIG. 35 is a schematic cross-sectional view showing a configuration of a part of a semiconductor memory device according to a fifth embodiment;

FIG. 36 is a schematic cross-sectional view for explaining a method of manufacturing same semiconductor memory device;

FIG. 37 is a schematic cross-sectional view for explaining same method of manufacturing; and

FIG. 38 is a schematic cross-sectional view for explaining same method of manufacturing.

### DETAILED DESCRIPTION

A semiconductor memory device according to one embodiment comprises: a plurality of memory block regions arranged in a first direction; a hook-up region arranged in the first direction with respect to the plurality of memory block regions; and a wiring region extending in the first direction and arranged with the plurality of memory block regions in a second direction intersecting the first direction. The plurality of memory block regions each comprise: a plurality of memory strings extending in the first direction and arranged in the second direction; and a first wiring extending in the second direction and commonly connected to the plurality of memory strings. The wiring region comprises a second wiring which extends in the first direction and is commonly connected to a plurality of the first wirings corresponding to the plurality of memory block regions. The hook-up region comprises a contact electrode which extends in a third direction intersecting the first direction and the second direction, and is electrically connected to the second wiring. A first transistor is provided in a current path between the first wiring and the second wiring.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of configurations, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a first configuration is said to be “connected between” a second configuration and a third configuration, it will sometimes mean that the first configuration, the second configuration, and the third configuration are connected in series, and the second configuration is connected to the third configuration via the first configuration.

Moreover, in the present specification, when a circuit, or the like, is said to “make electrically conductive” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting the first direction along this certain plane will sometimes be referred to as a second direction, and a direction intersecting this certain plane will sometimes be referred to as a third direction. These first direction, second direction, and third direction may correspond to any of the X-direction, the Y-direction, and the Z-direction, but need not do so.

Moreover, in the present specification, expressions

such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

### First Embodiment

### Configuration

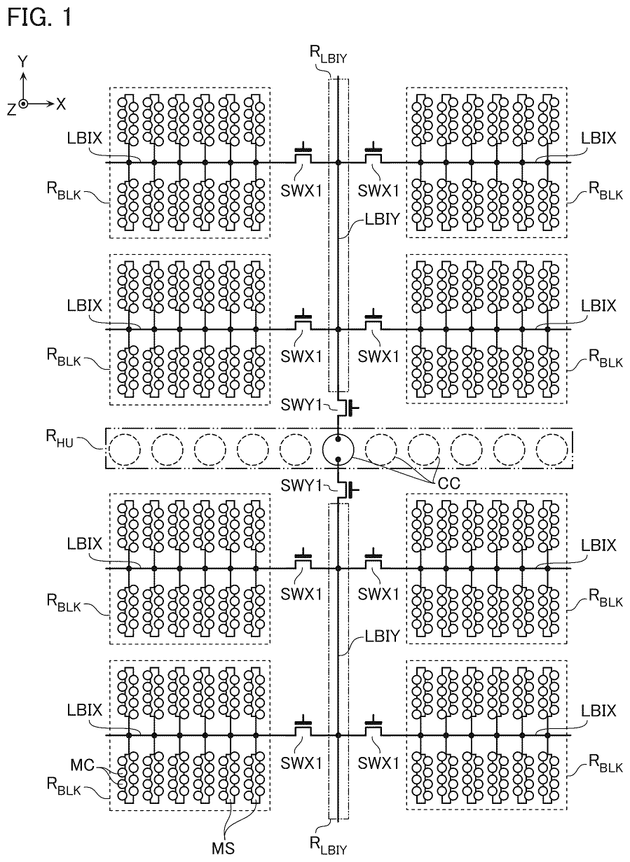

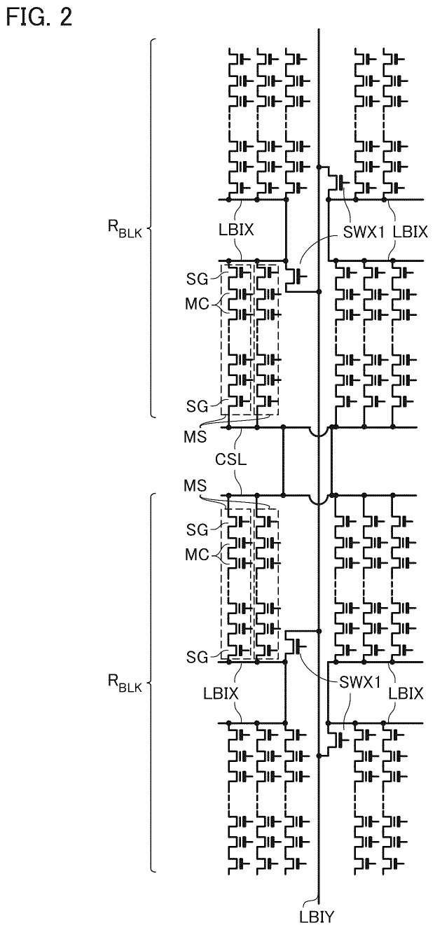

FIG. 1 is a schematic plan view showing a configuration of a part of a semiconductor memory device according to a first embodiment. FIG. 2 is a circuit diagram showing a configuration of a part of the semiconductor memory device according to the first embodiment. As shown in FIG. 1, for example, the semiconductor memory device according to the present embodiment comprises: a plurality of memory block regions R_{BLK}; a hook-up region R_{HU}; and a plurality of connecting line regions R_{LBIY}. The memory block regions R_{BLK} are arranged in a matrix in the X-direction and the Y-direction. The hook-up region R_{HU} is provided correspondingly to a plurality of the memory block regions R_{BLK} arranged in the Y-direction. The hook-up region R_{HU} is adjacent to the memory block region R_{BLK} in the Y-direction. The connecting line regions R_{LBIY} are each provided correspondingly to a plurality of the memory block regions R_{BLK} arranged in the Y-direction, and to the hook-up region R_{HU} corresponding to these memory block regions R_{BLK}. The connecting line regions R_{LBIY} are arranged with the plurality of memory block regions R_{BLK} in the X-direction.

The memory block region R_{BLK} is provided with: a plurality of memory strings MS extending in the Y-direction and arranged in the X-direction; and a local block connecting line LBIX extending in the X-direction and commonly connected to the plurality of memory strings MS.

As shown in FIG. 2, for example, the memory string MS includes a plurality of memory transistors (memory cells MC) and a select transistor SG connected to the plurality of memory transistors, that are connected in series. One end of the memory string MS is connected to the local block connecting line LBIX, and the other end of the memory string MS is connected to a source line CSL.

The connecting line region R_{LBIY} (FIG. 1) is provided with a local block connecting line LBIY extending in the Y-direction. A plurality of the local block connecting lines LBIX arranged in the Y-direction are commonly connected to the local block connecting line LBIY. Moreover, the local block connecting line LBIY is electrically connected to an unillustrated peripheral circuit via at least one of a plurality of contact electrodes CC provided in the hook-up region R_{HU}.

In the examples shown in FIGS. 1 and 2, a local block select transistor SWX1 is provided between the plurality of memory strings MS provided in one memory block region R_{BLK}, and the local block connecting line LBIY. Moreover, in the example shown in FIG. 1, a local block select transistor SWY1 is provided between the local block connecting line LBIY and the contact electrode CC.

The local block select transistor SWX1 functions as a switch for selecting at least one memory block region R_{BLK}.

Hereafter, a memory block region R_{BLK} that includes a memory cell MC representing a target of operation at a time of a write operation and read operation, will sometimes be referred to as a selected memory block region R_{BLK}, and a memory block region R_{BLK} that does not include a memory cell MC representing a target of operation at a time of a write operation and read operation, will sometimes be referred to as an unselected memory block region R_{BLK}.

At a time of a write operation and read operation, for example, the local block select transistor SWX1 provided between a selected memory block region R_{BLK} and the local block connecting line LBIY connected to the selected memory block region R_{BLK} is set to an ON state, and the local block select transistor SWX1 provided between an unselected memory block region R_{BLK} and the local block connecting line LBIY connected to the unselected memory block region R_{BLK} is set to an OFF state.

The local block select transistor SWY1 functions as a switch for selecting at least one local block connecting line LBIY.

At a time of a write operation and read operation, for example, the local block select transistor SWY1 provided between a local block connecting line LBIY connected to a selected memory block region R_{BLK} and the contact electrode CC connected to that local block connecting line LBIY is set to an ON state, and the local block select transistor SWY1 provided between another local block connecting line LBIY and the contact electrode CC connected to that local block connecting line LBIY is set to an OFF state.

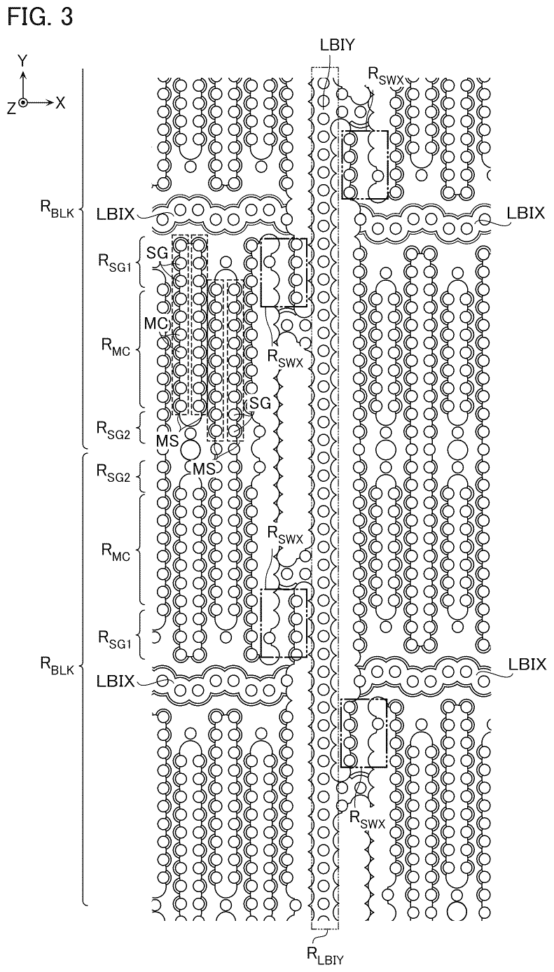

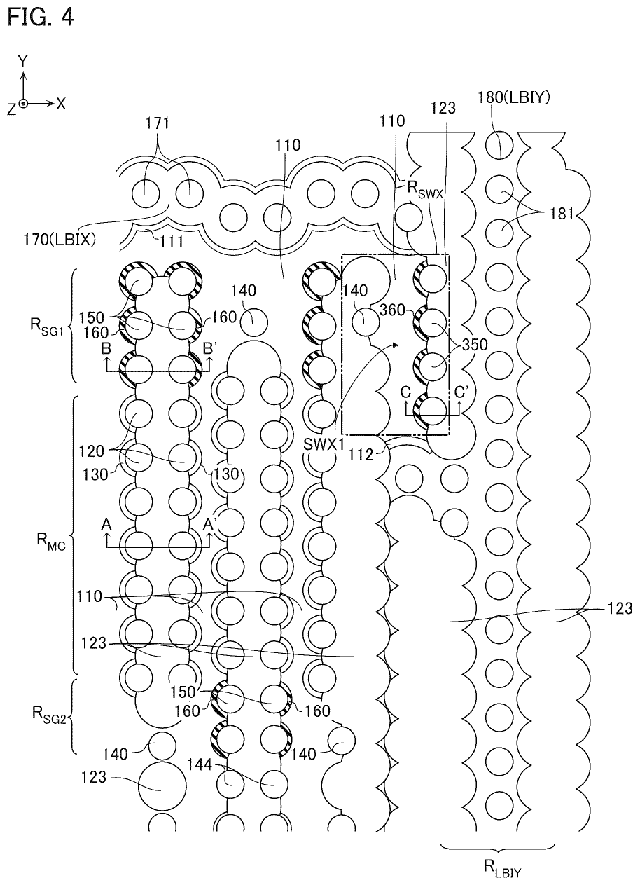

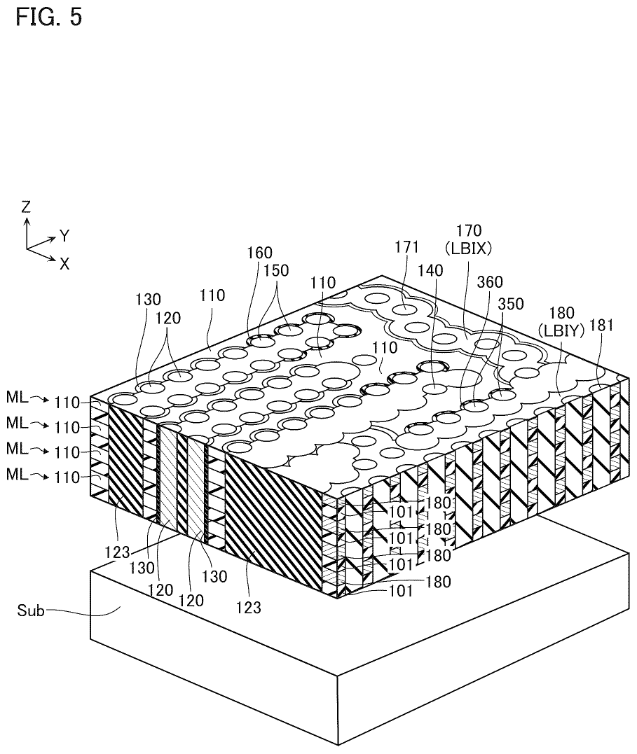

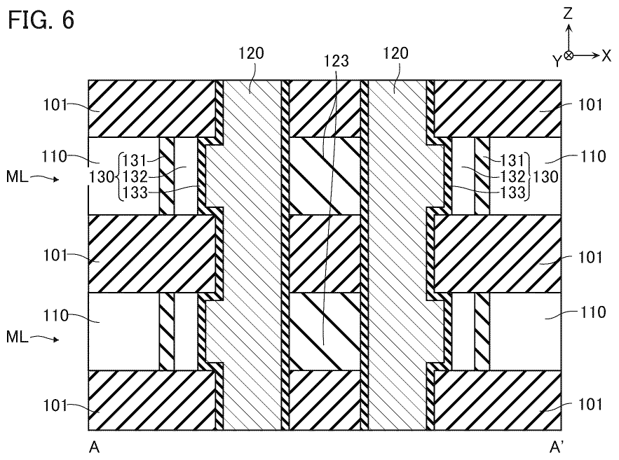

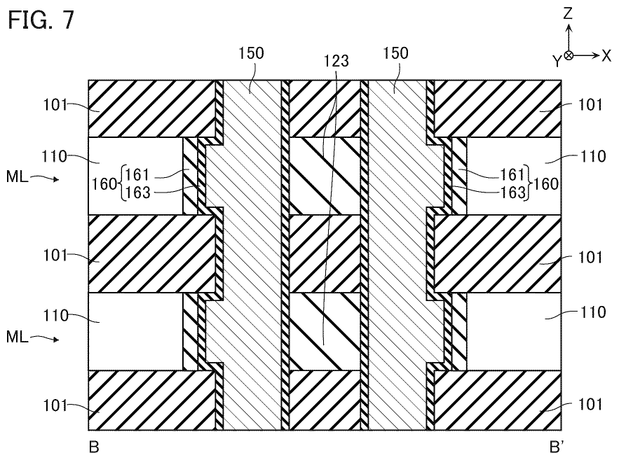

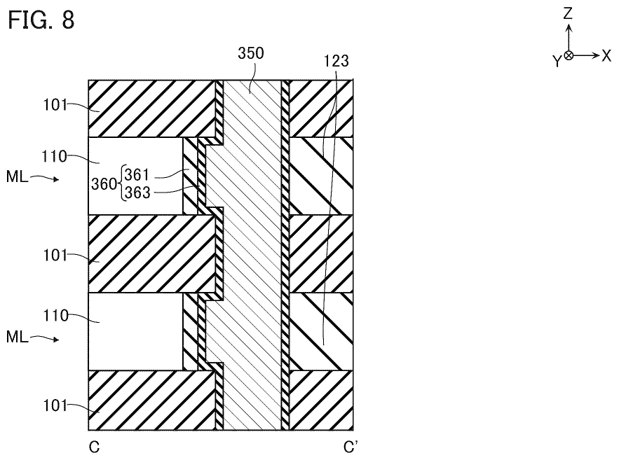

FIG. 3 is a schematic plan view showing a configuration of a part of the semiconductor memory device according to the first embodiment. FIG. 3 shows parts of two memory block regions R_{BLK} adjacent in the Y-direction. FIG. 4 is a schematic plan view showing an enlarged part of FIG. 3. Note that FIGS. 3 and 4 are plan views showing configurations of a later-mentioned memory layer ML. FIG. 5 is a schematic perspective view including the portion shown in FIG. 4. FIG. 6 is a schematic cross-sectional view in which the structure shown in FIG. 4 has been cut along the line A-A′ and viewed along a direction of the arrows. FIG. 7 is a schematic cross-sectional view in which the structure shown in FIG. 4 has been cut along the line B-B′ and viewed along a direction of the arrows. FIG. 8 is a schematic cross-sectional view in which the structure shown in FIG. 4 has been cut along the line C-C′ and viewed along a direction of the arrows.

FIG. 3 shows: the plurality of memory strings MS and the local block connecting line LBIX provided in the memory block region R_{BLK}; a region R_{SWX}; and the local block connecting line LBIY provided in the connecting line region R_{LBIY}.

Note that in the following description, regions provided with the plurality of memory cells MC, of the plurality of memory strings MS, will sometimes be referred to as memory cell regions R_{MC}, and regions provided with the plurality of select transistors SG, of the plurality of memory strings MS, will sometimes be referred to as select transistor regions R_{SG1}, R_{SG2}. The select transistor region R_{SG1} is provided at a closer position to the local block connecting line LBIX than is the select transistor region R_{SG2}.

FIG. 5 shows a part of a semiconductor substrate Sub. The semiconductor substrate Sub includes of the likes of silicon (Si) containing a P-type impurity such as boron (B), for example. As shown in FIG. 5, the semiconductor memory device according to the present embodiment comprises a plurality of memory layers ML arranged in the Z-direction, above the semiconductor substrate Sub. An insulating layer 101 of the likes of silicon oxide (SiO₂) is provided between two memory layers ML adjacent in the Z-direction.

The memory layer ML comprises a plurality of semiconductor layers 110 arranged in the X-direction. These plurality of semiconductor layers 110 each extend in the Y-direction over the plurality of memory cell regions R_{MC}, and the plurality of select transistor regions R_{SG1}, R_{SG2} described with reference to FIG. 3. The semiconductor layer 110 functions as channel regions of the serially-connected plurality of memory cells MC and select transistors SG, for example. The semiconductor layer 110 may include the likes of non-doped polycrystalline silicon (Si), for example.

In the memory block region R_{BLK}, as shown in FIG. 4, for example, an insulating layer 123 of the likes of silicon oxide (SiO₂) is provided between the semiconductor layers 110 adjacent in the X-direction.

In the memory cell region R_{MC}, as shown in FIG. 4, for example, a plurality of conductive layers 120 arranged in the Y-direction are provided between the semiconductor layer 110 and the insulating layer 123, and a gate insulating layer 130 is provided between each of the plurality of conductive layers 120 and the semiconductor layer 110.

The conductive layer 120 functions for example as gate electrodes of a plurality of the memory transistors, and as the word line connected to these gate electrodes, and so on. The conductive layer 120 may include the likes of titanium nitride (TiN), tungsten (W), and a stacked film of titanium nitride (TiN) and tungsten (W), for example. As shown in FIGS. 5 and 6, for example, the conductive layer 120 extends in the Z-direction penetrating the plurality of memory layers ML, and faces the semiconductor layer 110 in each of the memory layers ML.

As shown in FIG. 6, for example, the gate insulating layer 130 comprises: a tunnel insulating layer 131 provided on a side surface in the X-direction of the semiconductor layer 110; an electric charge accumulating layer 132 provided on a side surface in the X-direction of the tunnel insulating layer 131; and a block insulating layer 133 provided on a side surface in the X-direction of the electric charge accumulating layer 132.

The tunnel insulating layer 131 may include the likes of silicon oxide (SiO₂), for example.

The electric charge accumulating layer 132 may include the likes of polycrystalline silicon (Si), for example. Moreover, this polycrystalline silicon (Si) may include an N-type impurity such as phosphorus (P) or P-type impurity such as boron (B), but need not include these impurities.

The block insulating layer 133 may include the likes of silicon oxide (SiO₂), for example. Moreover, the block insulating layer 133 may include an insulating metal oxide film of aluminum oxide (AlO), hafnium oxide (HfO), or others.

As shown in FIG. 4, for example, the select transistor regions R_{SG1}, R_{SG2} are provided with a conductive layer 140, and a conductive layer 144 is provided in a vicinity of the select transistor region R_{SG2}.

The conductive layer 140 functions as the likes of a contact electrode for applying a voltage to the semiconductor layer 110, for example. The conductive layer 140 may include a semiconductor layer of the likes of polycrystalline silicon (Si) containing a P-type impurity such as boron (B), for example. The conductive layer 140 extends in the Z-direction penetrating the plurality of memory layers ML.

Note that the conductive layer 140 is sometimes provided as the likes of a contact electrode for applying a voltage to the semiconductor layer 110, in a region other than the select transistor regions R_{SG1}, R_{SG2}, too.

The conductive layer 144 functions as the likes of a contact electrode for applying a voltage to the semiconductor layer 110, for example. The conductive layer 144 may include a semiconductor layer of the likes of polycrystalline silicon (Si) containing an N-type impurity such as phosphorus (P), for example. The conductive layer 144 extends in the Z-direction penetrating the plurality of memory layers ML. The conductive layer 144 may function as a part of the source line CSL.

Note that the conductive layer 144 is sometimes provided as the likes of a contact electrode for applying a voltage to the semiconductor layer 110, in a region other than a vicinity of the select transistor region R_{SG2}, too.

Moreover, in the select transistor regions R_{SG1}, R_{SG2}, as shown in FIG. 4, for example, a plurality of conductive layers 150 arranged in the Y-direction are provided between the semiconductor layer 110 and the insulating layer 123, and a gate insulating layer 160 is provided between each of the plurality of conductive layers 150 and the semiconductor layer 110.

The conductive layer 150 functions for example as a gate electrode of the select transistor SG, and as a wiring connected to this gate electrode, and so on. The conductive layer 150 may include the likes of titanium nitride (TiN), tungsten (W), and a stacked film of titanium nitride (TiN) and tungsten (W), for example. As shown in FIG. 7, for example, the conductive layer 150 extends in the Z-direction penetrating the plurality of memory layers ML, and faces the semiconductor layer 110 in each of the memory layers ML.

As shown in FIG. 7, for example, the gate insulating layer 160 comprises: an insulating layer 161 provided on a side surface in the X-direction of the semiconductor layer 110; and an insulating layer 163 provided on a side surface in the X-direction of the insulating layer 161.

The insulating layer 161 may include the likes of silicon oxide (SiO₂), for example.

The insulating layer 163 may include the likes of silicon oxide (SiO₂), for example. Moreover, the insulating layer 163 may include an insulating metal oxide film of aluminum oxide (AlO), hafnium oxide (HfO), or others.

Note that the configuration of the gate insulating layer 160 shown in FIG. 7 is merely an exemplification, and that, for example, the gate insulating layer 160 may have a similar configuration to the gate insulating layer 130. In such a case, for example, the gate insulating layer 160 may comprise a similar layer to the electric charge accumulating layer 132 (FIG. 6) provided between the insulating layer 161 and the insulating layer 163.

As shown in FIG. 4, for example, in a region adjacent in the Y-direction to the select transistor region R_{SG1}, the memory layer ML comprises a conductive layer 170 extending in substantially the X-direction. Moreover, a plurality of insulating layers 171 arranged along the conductive layer 170 are provided.

The conductive layer 170 functions as the local block connecting line LBIX (FIGS. 1 and 2), for example. The conductive layer 170 may include a conductive layer of the likes of titanium nitride (TiN), for example. The conductive layer 170 is connected to the plurality of semiconductor layers 110 via a semiconductor layer 111. The conductive layer 170 is electrically connected to the semiconductor layers 110 in the plurality of memory strings MS arranged on both sides in the Y-direction of the conductive layer 170, for example.

The semiconductor layer 111 is provided on both side surfaces in the Y-direction of the conductive layer 170. The semiconductor layer 111 may include the likes of polycrystalline silicon (Si) containing an N-type impurity such as phosphorus (P), for example.

The insulating layer 171 may include the likes of silicon oxide (SiO₂), for example. The insulating layer 171 extends in the Z-direction penetrating the plurality of memory layers ML.

As shown in FIG. 4, for example, in the connecting line region R_{LBIY}, the memory layer ML comprises a conductive layer 180 extending in the Y-direction. Moreover, the connecting line region R_{LBIY} is provided with a plurality of insulating layers 181 arranged along the conductive layer 180.

The conductive layer 180 functions as the local block connecting line LBIY (FIGS. 1 and 2), for example. The conductive layer 180 may include a conductive layer of the likes of titanium nitride (TiN), for example. The conductive layer 180 is connected to the semiconductor layer 110 in the region R_{SWX} via a semiconductor layer 112.

The semiconductor layer 112 is provided on a part of a side surface of the conductive layer 180. The semiconductor layer 112 may include a similar material to the semiconductor layer 111, for example.

The insulating layer 181 may include the likes of silicon oxide (SiO₂), for example. The insulating layer 181 extends in the Z-direction penetrating the plurality of memory layers ML, as shown in FIG. 5, for example.

The region R_{SWX} is provided at a position adjacent to the local block connecting line LBIX and the local block connecting line LBIY, as shown in FIGS. 3 and 4, for example. The region R_{SWX} is provided with the local block select transistor SWX1 (FIG. 4).

In the region R_{SWX}, as shown in FIG. 4, for example, a plurality of conductive layers 350 arranged in the Y-direction are provided between the semiconductor layer 110 and the insulating layer 123, and a gate insulating layer 360 is provided between each of the plurality of conductive layers 350 and the semiconductor layer 110.

The conductive layer 350 functions for example as a gate electrode of the local block select transistor SWX1, and as a wiring connected to this gate electrode, and so on. The conductive layer 350 may include the likes of titanium nitride (TiN), tungsten (W), and a stacked film of titanium nitride (TiN) and tungsten (W), for example. As shown in FIG. 8, for example, the conductive layer 350 extends in the Z-direction penetrating the plurality of memory layers ML, and faces the semiconductor layer 110 in each of the memory layers ML.

As shown in FIG. 8, for example, the gate insulating layer 360 comprises: an insulating layer 361 provided on a side surface in the X-direction of the semiconductor layer 110; and an insulating layer 363 provided on a side surface in the X-direction of the insulating layer 361.

The insulating layer 361 may include the likes of silicon oxide (SiO₂), for example.

The insulating layer 363 may include the likes of silicon oxide (SiO₂), for example. Moreover, the insulating layer 363 may include an insulating metal oxide film of aluminum oxide (AlO), hafnium oxide (HfO), or others.

Note that the configuration of the gate insulating layer 360 shown in FIG. 8 is merely an exemplification, and that, for example, the gate insulating layer 360 may have a similar configuration to the gate insulating layer 130. In such a case, for example, the gate insulating layer 360 may comprise a similar layer to the electric charge accumulating layer 132 (FIG. 6) provided between the insulating layer 361 and the insulating layer 363.

In the example shown in FIG. 4, a region on one side in the X-direction with respect to the semiconductor layer 110, in the region R_{SWX} is provided with the plurality of conductive layers 350, and a region on the other side in the X-direction with respect to the semiconductor layer 110, in the region R_{SWX} is provided with the conductive layer 140. The conductive layer 140 is provided between the insulating layer 123 and the semiconductor layer 110. This conductive layer 140 functions as a body contact electrode of the local block select transistor SWX1, for example.

Note that such a configuration is merely an exemplification, and that specific configuration is appropriately adjustable. For example, a plurality of the conductive layers 350 may be provided not only in the region on one side in the X-direction with respect to the semiconductor layer 110, in the region R_{SWX}, but also in the region on the other side in the X-direction with respect to the semiconductor layer 110, in the region R_{SWX}. These plurality of conductive layers 350 may be provided between the insulating layer 123 and the semiconductor layer 110, for example. Moreover, the gate insulating layer 360 may be provided between each of these plurality of conductive layers 350 and the semiconductor layer 110.

Note that the conductive layers 120, 150, 350 shown in FIG. 4, for example, may each be provided arranged in the Y-direction at equal pitches.

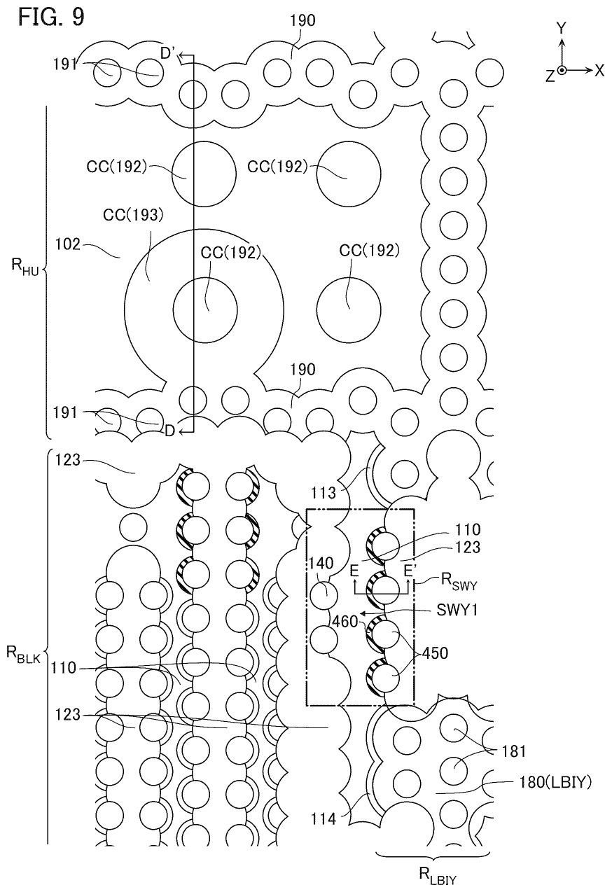

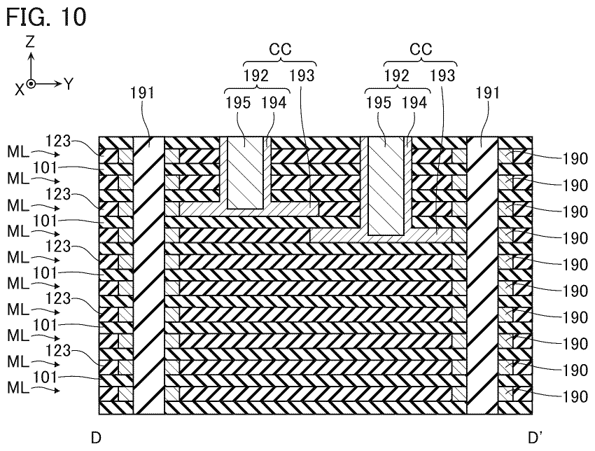

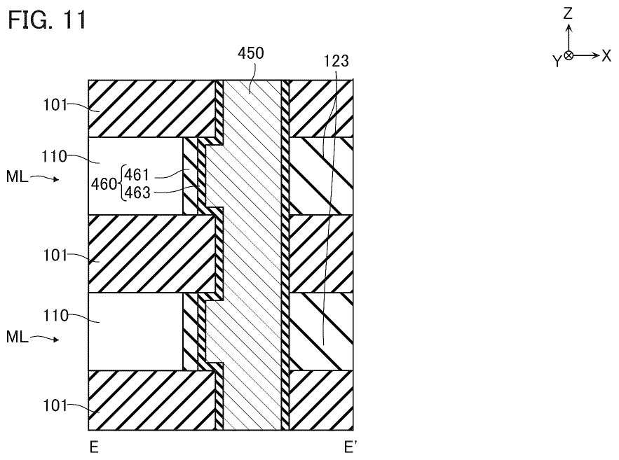

FIG. 9 is a schematic plan view showing a configuration of a part of the hook-up region R_{HU}. FIG. 10 is a schematic cross-sectional view in which the structure shown in FIG. 9 has been cut along the line D-D′ and viewed along a direction of the arrows. FIG. 11 is a schematic cross-sectional view in which the structure shown in FIG. 9 has been cut along the line E-E′ and viewed along a direction of the arrows.

In the hook-up region R_{HU}, as shown in FIG. 9, for example, the memory layer ML comprises a plurality of conductive layers 190 extending in substantially the X-direction. Moreover, the hook-up region R_{HU} is provided with a plurality of insulating layers 191 arranged along the conductive layer 190. Moreover, a region R_{SWY} is provided between the hook-up region R_{HU} and the connecting line region R_{LBIY}.

The conductive layer 190 functions as a lead-out wiring to each memory layer ML from the contact electrode CC, for example. The conductive layer 190 may include a conductive layer of the likes of titanium nitride (TiN), for example. The conductive layer 190 is connected to the semiconductor layer 110 in the region R_{SWY} via a semiconductor layer 113.

The semiconductor layer 113 is provided on a part of a side surface of the conductive layer 190. The semiconductor layer 113 may include a similar material to the semiconductor layer 111, for example.

The insulating layer 191 may include an insulating layer of the likes of silicon oxide (SiO₂), for example. The insulating layer 191 extends in the Z-direction penetrating the plurality of memory layers ML.

Moreover, as shown in FIG. 9, for example, the hook-up region R_{HU} is provided with a plurality of the contact electrodes CC arranged in the X-direction and the Y-direction along the conductive layer 190. Between the plurality of contact electrodes CC, the memory layer ML comprises an insulating layer 102 of the likes of silicon nitride (SiN), for example.

As shown in FIG. 10, for example, the contact electrode CC comprises: a portion 192 of substantially circular column-like shape; and a portion 193 of substantially disk-like shape, provided in a lower end portion of this portion 192.

The portion 192 may include, for example: a barrier conductive layer 194 of the likes of titanium nitride (TiN); and a conductive layer 195 of the likes of tungsten (W). The portion 192 extends in the Z-direction penetrating the plurality of memory layers ML.

The portion 193 may include the barrier conductive layer 194 of the likes of titanium nitride (TiN), for example. The portion 193 is included in any of the memory layers ML, and is connected to a side surface in the X-direction of the conductive layer 190 included in the any of the memory layers ML. Note that the hook-up region R_{HU} may be provided with contact electrodes CC corresponding to all of the memory layers ML. In this case, the number of contact electrodes CC may match the number of memory layers ML, or may exceed the number of memory layers ML.

The region R_{SWY} is provided with the local block select transistor SWY1.

In the region R_{SWY}, as shown in FIG. 9, for example, a plurality of conductive layers 450 arranged in the Y-direction are provided between the semiconductor layer 110 and the insulating layer 123, and a gate insulating layer 460 is provided between each of the plurality of conductive layers 450 and the semiconductor layer 110.

The conductive layer 450 functions for example as a gate electrode of the local block select transistor SWY1, and as a wiring connected to this gate electrode, and so on. The conductive layer 450 may include the likes of titanium nitride (TiN), tungsten (W), and a stacked film of titanium nitride (TiN) and tungsten (W), for example. As shown in FIG. 11, for example, the conductive layer 450 extends in the Z-direction penetrating the plurality of memory layers ML, and faces the semiconductor layer 110 in each of the memory layers ML.

As shown in FIG. 11, for example, the gate insulating layer 460 comprises: an insulating layer 461 provided on a side surface in the X-direction of the semiconductor layer 110; and an insulating layer 463 provided on a side surface in the X-direction of the insulating layer 461.

The insulating layer 461 may include the likes of silicon oxide (SiO₂), for example.

The insulating layer 463 may include the likes of silicon oxide (SiO₂), for example. Moreover, the insulating layer 463 may include an insulating metal oxide film of aluminum oxide (AlO), hafnium oxide (HfO), or others.

Note that the configuration of the gate insulating layer 460 shown in FIG. 11 is merely an exemplification, and that, for example, the gate insulating layer 460 may have a similar configuration to the gate insulating layer 130. In such a case, for example, the gate insulating layer 460 may comprise a similar layer to the electric charge accumulating layer 132 (FIG. 6) provided between the insulating layer 461 and the insulating layer 463.

Note that the conductive layer 180 (local block connecting line LBIY) is connected to the semiconductor layer 110 in the region R_{SWY} via a semiconductor layer 114.

The semiconductor layer 114 is provided on a part of a side surface of the conductive layer 180. The semiconductor layer 114 may include a similar material to the semiconductor layer 111, for example.

In the example shown in FIG. 9, a region on one side in the X-direction with respect to the semiconductor layer 110, in the region R_{SWY} is provided with the plurality of conductive layers 450, and a region on the other side in the X-direction with respect to the semiconductor layer 110, in the region R_{SWY} is provided with the conductive layer 140. The conductive layer 140 is provided between the insulating layer 123 and the semiconductor layer 110. This conductive layer 140 functions as a body contact electrode of the local block select transistor SWY1, for example.

Note that such a configuration is merely an exemplification, and that specific configuration is appropriately adjustable. For example, a plurality of the conductive layers 450 may be provided not only in the region on one side in the X-direction with respect to the semiconductor layer 110, in the region R_{SWY}, but also in the region on the other side in the X-direction with respect to the semiconductor layer 110, in the region R_{SWY}. These plurality of conductive layers 450 may be provided between the insulating layer 123 and the semiconductor layer 110, for example. Moreover, the gate insulating layer 460 may be provided between each of these plurality of conductive layers 450 and the semiconductor layer 110.

### Advantages

There is known a semiconductor memory device comprising layers arranged in the Z-direction, each of which comprises a plurality of semiconductor layers and a plurality of conductive layers. In such a semiconductor memory device, a hook-up region for connection to be made between each of the layers arranged in the Z-direction and a peripheral circuit, is sometimes provided. The hook-up region is provided with a plurality of contact electrodes extending in the Z-direction. Moreover, in such a semiconductor memory device, each of the layers arranged in the Z-direction is provided with a local wiring that connects the contact electrode and the plurality of semiconductor layers.

Although chip area can be reduced when the number of semiconductor layers connected to the local wiring is increased in each of the layers arranged in the Z-direction, it has sometimes occurred that parasitic capacitance associated with the local wiring and the semiconductor layers increases, and speed of operation drops.

In the present embodiment, the local block select transistor SWX1 is provided between the local block connecting line LBIX and the local block connecting line LBIY, and the local block select transistor SWY1 is provided between the local block connecting line LBIY and the contact electrode CC.

Such a configuration makes it possible for the local block select transistor SWX1 connected to a selected memory block region R_{BLK} to be set to an ON state, and the local block select transistor SWX1 connected to an unselected memory block region R_{BLK} to be set to an OFF state, whereby a portion of parasitic capacitance originating from the unselected memory block region R_{BLK} is reduced, and speed of operation is improved.

Moreover, such a configuration makes it possible for the local block select transistor SWY1 connected to a selected memory block region R_{BLK} to be set to an ON state, and the local block select transistor SWY1 all of the plurality of memory block regions R_{BLK} connected to which are unselected, to be set to an OFF state, whereby a portion of parasitic capacitance originating from the local block connecting line LBIY all of the memory block regions R_{BLK} connected to which are unselected is also reduced, and speed of operation is further improved.

### Modified Example

A configuration of the local block connecting line LBIX and the region R_{SWX} of the kind exemplified in FIGS. 3 to 5 is merely an exemplification, and a specific configuration is appropriately adjustable.

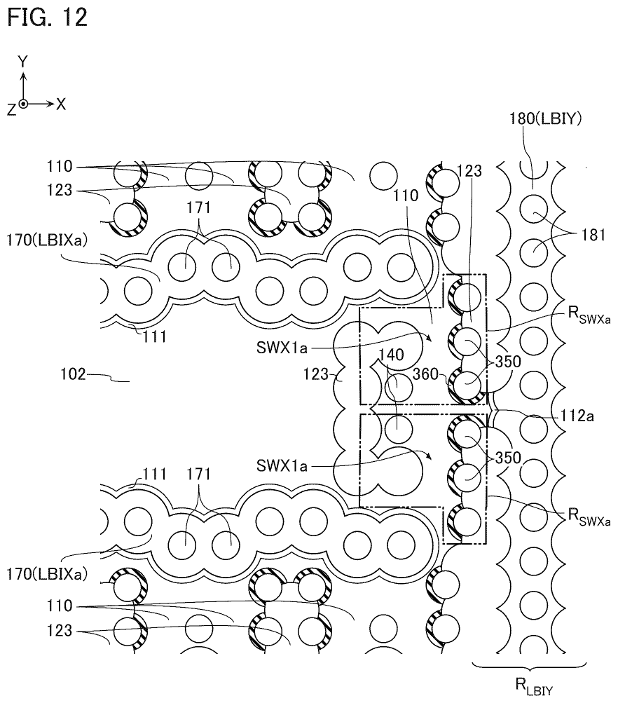

FIG. 12 is a schematic plan view for explaining a modified example of the semiconductor memory device according to the first embodiment. For example, a configuration according to the present modified example exemplified in FIG. 12 comprises two local block connecting lines LBIXa arranged in the Y-direction, instead of the local block connecting line LBIX, and comprises two regions R_{SWXa} provided between the two local block connecting lines LBIXa, instead of the region R_{SWX}.

The local block connecting line LBIXa is basically provided similarly to the local block connecting line LBIX (FIG. 4). However, the conductive layer 170 functioning as the local block connecting line LBIXa (FIG. 12) is electrically connected to the semiconductor layers 110 in the plurality of memory strings MS arranged on one side in the Y-direction of the conductive layer 170, for example.

The region R_{SWXa} is provided with a local block select transistor SWX1a.

The local block select transistor SWX1a is basically provided similarly to the local block select transistor SWX1 (FIG. 4). However, the local block select transistor SWX1a is connected to the conductive layer 180 via a semiconductor layer 112a provided on a side surface of the conductive layer 180, for example. The semiconductor layer 112a includes a similar material to the semiconductor layer 112.

In such a configuration, the number of memory strings MS connected to one local block connecting line LBIXa will be half that of the configuration according to the first embodiment (FIGS. 3 to 5), hence a further reduction in parasitic capacitance is possible.

### Second Embodiment

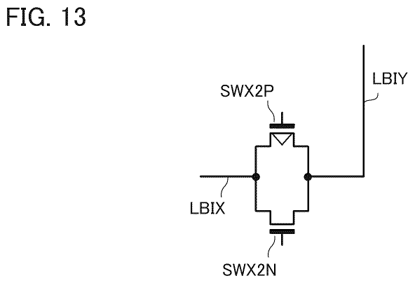

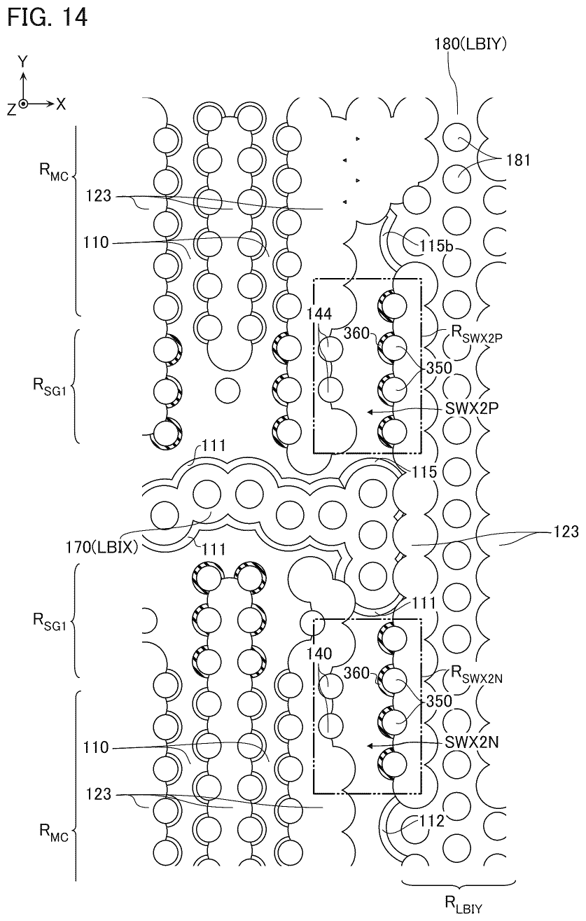

FIG. 13 is a circuit diagram showing a configuration of a part of a semiconductor memory device according to a second embodiment. FIG. 14 is a schematic plan view showing a configuration of a part of the semiconductor memory device according to the second embodiment.

Note that in the following description, configurations similar to in the first embodiment will be assigned with the same symbols as in the first embodiment, and descriptions thereof omitted.

The semiconductor memory device according to the present embodiment is basically configured similarly to the semiconductor memory device according to the first embodiment. However, in the semiconductor memory device according to the present embodiment, the local block connecting line LBIX and the local block connecting line LBIY do not have the local block select transistor SWX1 (FIG. 1) provided therebetween, but instead, have local block select transistors SWX2N, SWX2P provided in parallel therebetween.

The local block select transistors SWX2N, SWX2P function as a switch for selecting at least one memory block region R_{BLK}. The local block select transistor SWX2N is an N-type transistor adopting electrons as carriers. The local block select transistor SWX2N is connected to the conductive layers 170, 180 via the semiconductor layers 111, 112 of the likes of polycrystalline silicon (Si) containing an N-type impurity. The local block select transistor SWX2P is a P-type transistor adopting positive holes as carriers. The local block select transistor SWX2P is connected to the conductive layers 170, 180 via semiconductor layers 115, 115b of the likes of polycrystalline silicon (Si) containing a P-type impurity.

At a time of a write operation and read operation, for example, at least one of the local block select transistors SWX2N, SWX2P provided between a selected memory block region R_{BLK} and the local block connecting line LBIY connected to the selected memory block region R_{BLK} is set to an ON state, and both of the local block select transistors SWX2N, SWX2P provided between an unselected memory block region R_{BLK} and the local block connecting line LBIY connected to the unselected memory block region R_{BLK} are set to an OFF state.

Moreover, as shown in FIG. 14, for example, the semiconductor memory device according to the present embodiment comprises a region R_{SWX2N} and a region R_{SWX2P} (FIG. 14), instead of the single region R_{SWX} (FIG. 4).

The region R_{SWX2N} is provided at a position adjacent to one side in the Y-direction of the local block connecting line LBIX and to the local block connecting line LBIY, as shown in FIG. 14, for example. The region R_{SWX2N} is provided with the local block select transistor SWX2N.

The local block select transistor SWX2N is basically provided similarly to the local block select transistor SWX1 (FIG. 4).

The region R_{SWX2P} is provided at a position adjacent to the other side in the Y-direction of the local block connecting line LBIX and to the local block connecting line LBIY, as shown in FIG. 14, for example. The region R_{SWX2P} is provided with the local block select transistor SWX2P.

The local block select transistor SWX2P is basically provided similarly to the local block select transistor SWX1 (FIG. 4). However, the region R_{SWX2P} provided with the local block select transistor SWX2P comprises a conductive layer 144 instead of the conductive layer 140.

Moreover, the local block select transistor SWX2P is connected to the conductive layer 170 via the semiconductor layer 115 which is provided on a part of a side surface in the Y-direction of the conductive layer 170, for example. The semiconductor layer 115 may include the likes of polycrystalline silicon (Si) containing a P-type impurity such as boron (B), for example.

Moreover, the local block select transistor SWX2P is connected to the conductive layer 180 via the semiconductor layer 115b which is provided on a side surface in the X-direction of the conductive layer 180, for example. The semiconductor layer 115b may include a similar material to the semiconductor layer 115.

### Advantages

In the present embodiment, the local block select transistors SWX2N, SWX2P being respectively N-type and P-type transistors, are provided in parallel between the local block connecting line LBIX and the local block connecting line LBIY. Such a configuration enables voltage transfer between the local block connecting line LBIX and the local block connecting line LBIY to be surely performed in the memory layer ML being the operation target, even when capacitive coupling of fellow memory layers ML arranged adjacently in the Z-direction is strong.

### Method of Manufacturing

FIGS. 15 to 32 are schematic plan views or cross-sectional views for explaining a method of manufacturing the semiconductor memory devices according to the first and second embodiments. FIGS. 15, 19, 21, 23, 25, 27, 29, and 31 are drawings for explaining methods of manufacturing the semiconductor layers 110, 111, 112, 115, the conductive layers 120, 140, 144, 150, 170, 180, 350, the insulating layers 123, 171, 181, and the gate insulating layers 130, 160, 360 according to the first and second embodiments, hence schematically express these layers on a single plane. Note that the conductive layer 450 and the gate insulating layer 460 are basically formed similarly to the conductive layers 150, 350 and the gate insulating layers 160, 360, hence are omitted.

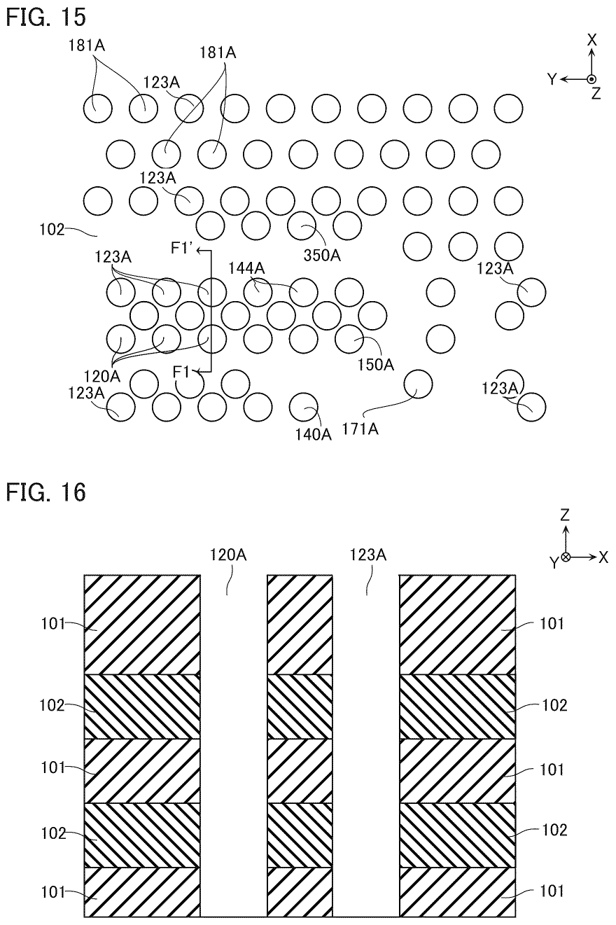

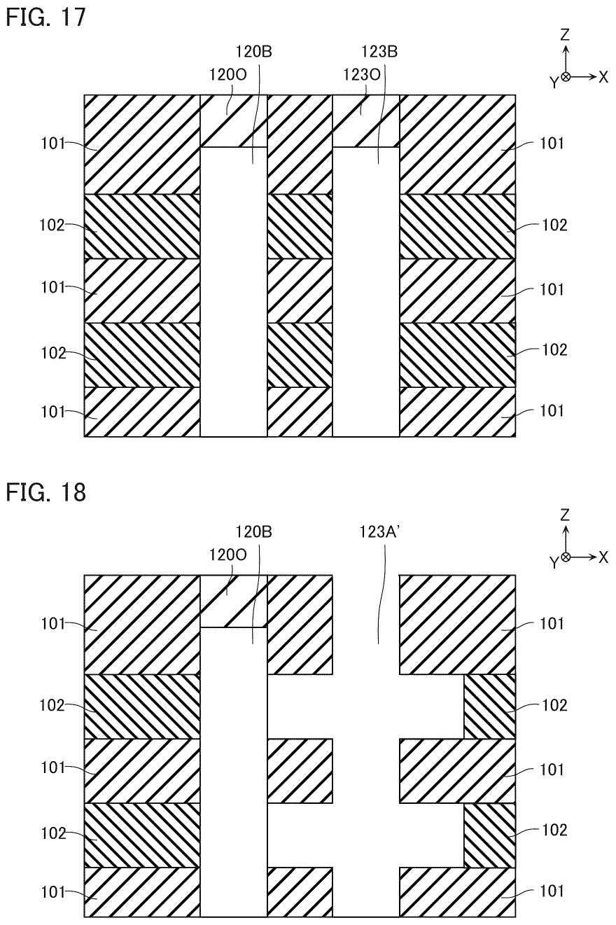

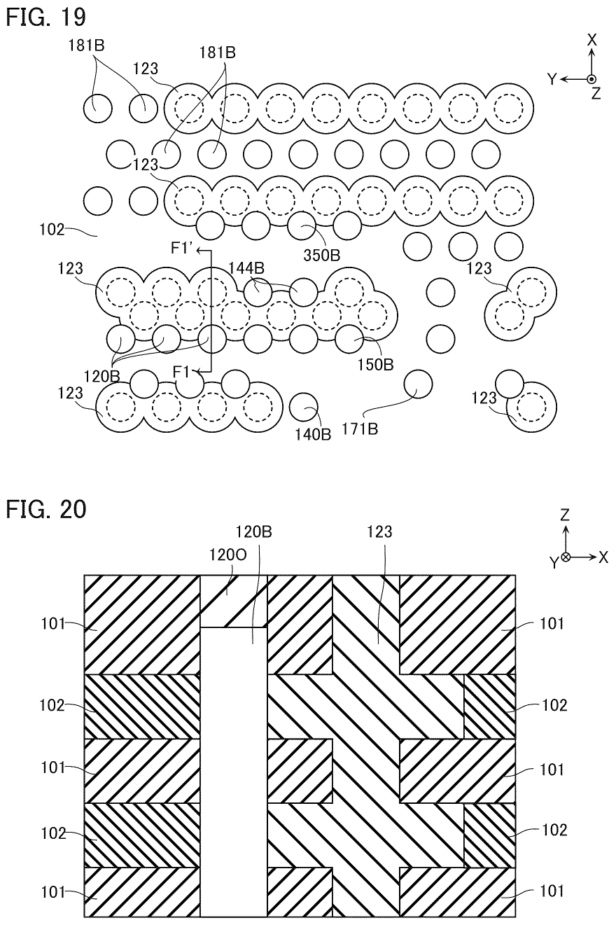

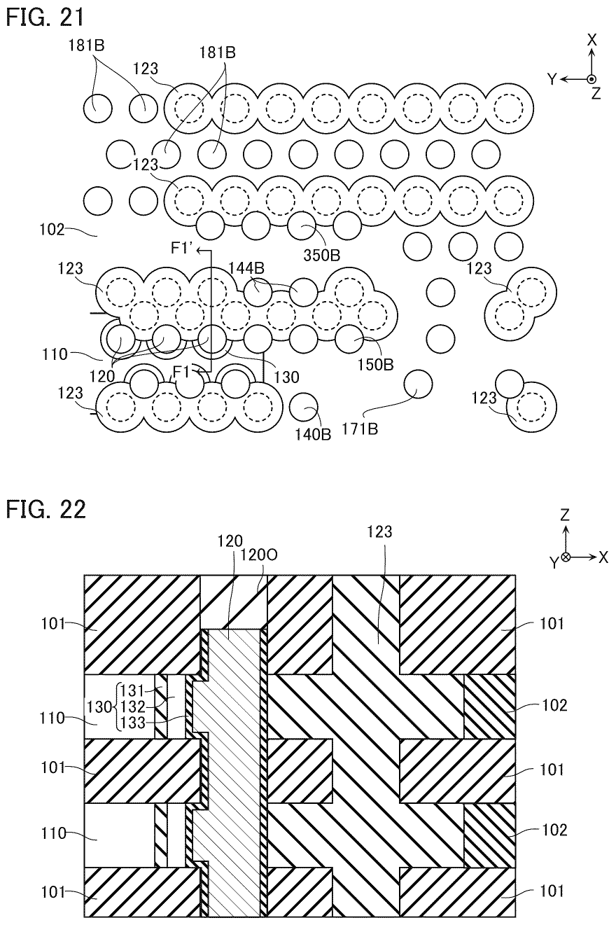

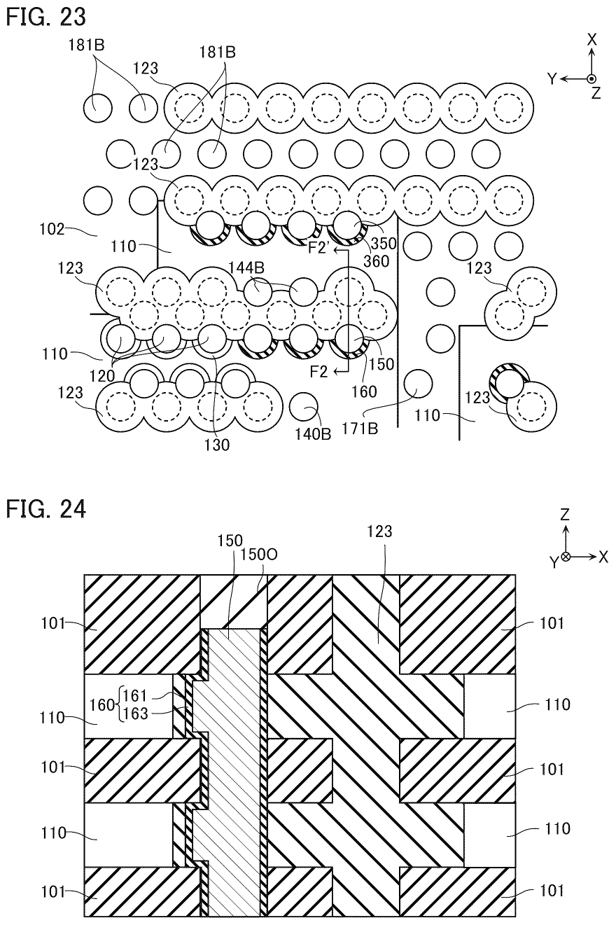

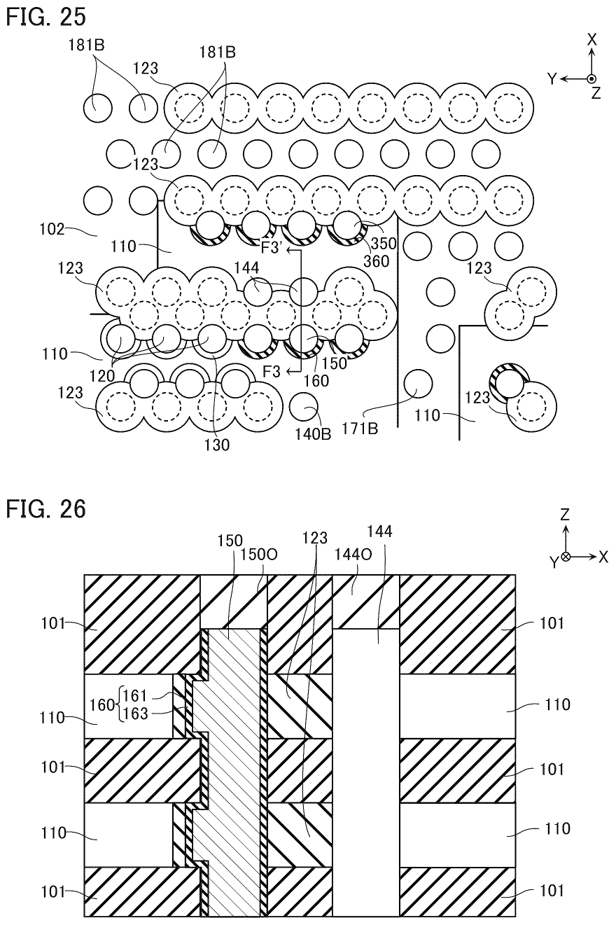

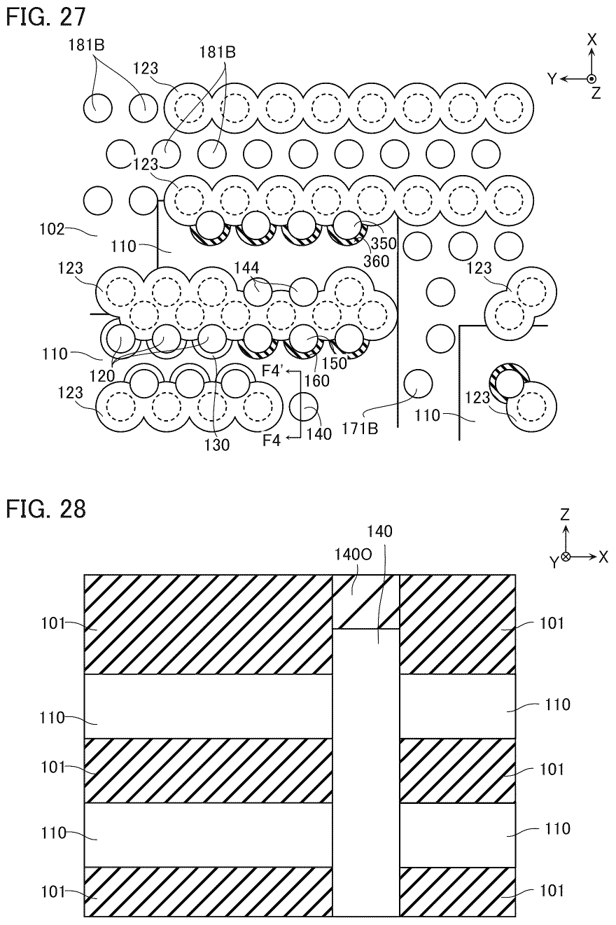

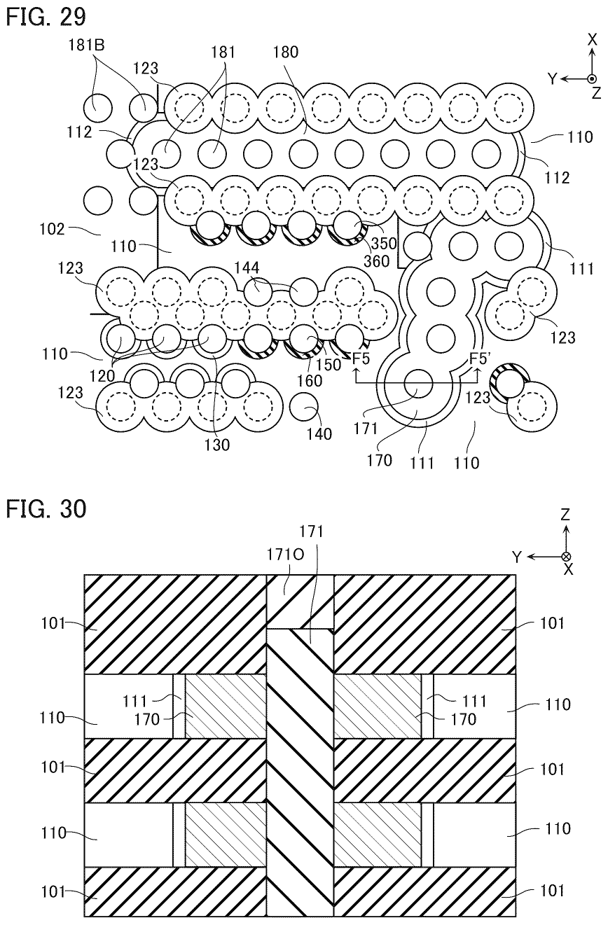

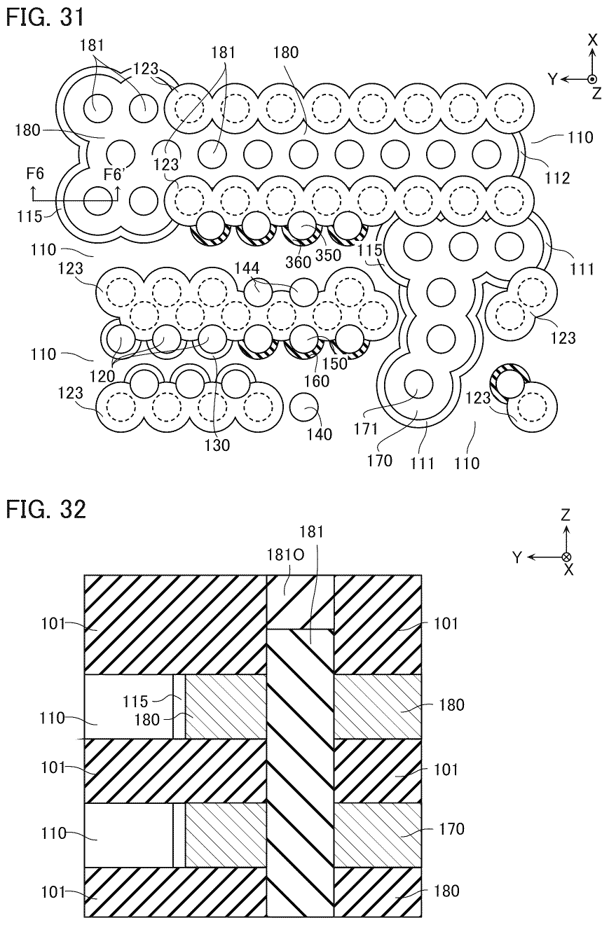

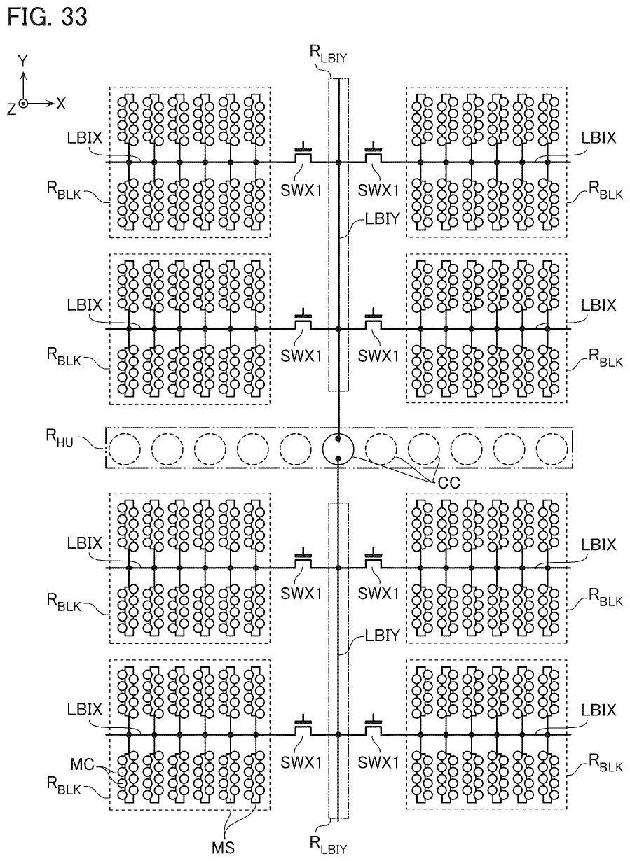

FIG. 16 is a schematic cross-sectional view in which the structure shown in FIG. 15 has been cut along the line F1-F1′ and viewed along a direction of the arrows. FIGS. 17 and 18 are cross-sectional views of portions corresponding to FIG. 16. FIG. 20 is a schematic cross-sectional view in which the structure shown in FIG. 19 has been cut along the line F1-F1′ and viewed along a direction of the arrows. FIG. 22 is a schematic cross-sectional view in which the structure shown in FIG. 21 has been cut along the line F1-F1′ and viewed along a direction of the arrows. FIG. 24 is a schematic cross-sectional view in which the structure shown in FIG. 23 has been cut along the line F2-F2′ and viewed along a direction of the arrows. FIG. 26 is a schematic cross-sectional view in which the structure shown in FIG. 25 has been cut along the line F3-F3′ and viewed along a direction of the arrows. FIG. 28 is a schematic cross-sectional view in which the structure shown in FIG. 27 has been cut along the line F4-F4′ and viewed along a direction of the arrows. FIG. 30 is a schematic cross-sectional view in which the structure shown in FIG. 29 has been cut along the line F5-F5′ and viewed along a direction of the arrows. FIG. 32 is a schematic cross-sectional view in which the structure shown in FIG. 31 has been cut along the line F6-F6′ and viewed along a direction of the arrows.

In same method of manufacturing, as shown in FIG. 16, for example, a plurality of the insulating layers 101 and a plurality of the insulating layers 102 are alternately formed. This step is performed by the likes of CVD (Chemical Vapor Deposition), for example.

Next, as shown in FIGS. 15 and 16, for example, openings 120A, 123A, 140A, 144A, 150A, 171A, 181A, 350A are formed. These openings 120A, 123A, 140A, 144A, 150A, 171A, 181A, 350A extend in the Z-direction similarly to the openings 120A, 123A shown in FIG. 16, and expose side surfaces in the X-direction of the plurality of insulating layers 101 and the plurality of insulating layers 102 arranged in the Z-direction. This step is performed by the likes of RIE (Reactive Ion Etching), for example.

Next, as shown in FIG. 17, for example, sacrifice layers 120B, 123B including the likes of silicon oxide (SiO₂) and amorphous silicon (Si), or carbon (C), and insulating layers 120O, 123O of the likes of silicon oxide (SiO₂), are sequentially formed inside the openings 120A, 123A. This step is performed by the likes of CVD, for example.

Moreover, similarly to in the step shown in FIG. 17, sacrifice layers 140B, 144B, 150B, 171B, 181B, 350B (refer to FIG. 19) are also formed, and in upper portions of these sacrifice layers, insulating layers 140O, 144O, 150O, 171O, 181O, 350O of the likes of silicon oxide (SiO₂) also formed inside the openings 140A, 144A, 150A, 171A, 181A, 350A.

Next, as shown in FIG. 18, for example, the insulating layer 123O and the sacrifice layer 123B are removed to form an opening, and then parts of the insulating layers 102 are removed via that opening to form an opening 123A′. Parts of a side surface in the X-direction of the sacrifice layer 120B are exposed in the opening 123A′. This step is performed by the likes of RIE and wet etching, for example.

Next, as shown in FIGS. 19 and 20, for example, the insulating layer 123 is formed inside the opening 123A′. This step is performed by the likes of CVD, for example.

Next, as shown in FIGS. 21 and 22, for example, the insulating layer 120O and the sacrifice layer 120B are removed to form an opening 120A (refer to FIG. 6), and then parts of the insulating layers 102 are removed via the opening 120A. In addition, the semiconductor layer 110, the tunnel insulating layer 131, and the electric charge accumulating layer 132 are sequentially formed in a space created by removing the parts of the insulating layers 102, via the opening 120A, and moreover, the block insulating layer 133 and the conductive layer 120, and the insulating layer 120O are formed in the opening 120A. This step is performed by the likes of RIE, CVD, and wet etching, for example.

Next, as shown in FIGS. 23 and 24, for example, the insulating layers 150O, 350O and the sacrifice layers 150B, 350B are removed to form openings 150A, 350A, and then parts of the insulating layers 102 are removed via the openings 150A, 350A. In addition, the semiconductor layer 110, and the insulating layers 161, 361 are sequentially formed in spaces created by removing the parts of the insulating layers 102, via the openings 150A, 350A, and moreover, the insulating layers 163, 363 and the conductive layers 150, 350, and the insulating layers 150O, 350O are formed in the openings 150A, 350A. This step is performed by the likes of RIE, CVD, and wet etching, for example.

Next, as shown in FIGS. 25 and 26, for example, the insulating layer 144O and the sacrifice layer 144B are removed to form an opening 144A, and the conductive layer 144 and the insulating layer 144O are formed in the opening 144A. This step is performed by the likes of RIE and CVD, for example.

Next, as shown in FIGS. 27 and 28, for example, the insulating layer 140O and the sacrifice layer 140B are removed to form an opening 140A, and the conductive layer 140 and the insulating layer 140O are formed in the opening 140A. This step is performed by the likes of RIE and CVD, for example.

Next, as shown in FIGS. 29 and 30, for example, the insulating layers 171O and the sacrifice layers 171B, and parts of the insulating layers 181O and the sacrifice layers 181B are removed to form openings 171A, 181A, and then parts of the semiconductor layers 110 and parts of the insulating layers 102 are removed via the openings 171A, 181A. In addition, the semiconductor layer 110, the semiconductor layers 111, 112, and the conductive layers 170, 180 are sequentially formed in spaces created by removing the parts of the insulating layers 102, via the openings 171A, 181A, and moreover, the insulating layer 171 and the insulating layer 171O are formed in the openings 171A, and the insulating layer 181 and the insulating layer 181O formed in the openings 181A. This step is performed by the likes of RIE, CVD, and wet etching, for example.

Next, as shown in FIGS. 31 and 32, for example, the remaining parts of the insulating layers 181O and the sacrifice layers 181B are removed to form openings 181A, and then parts of the semiconductor layers 110, parts of the insulating layers 102, and parts of the semiconductor layers 112 are removed via the openings 181A. In addition, the semiconductor layer 110, the semiconductor layer 115, and the conductive layer 180 are sequentially formed in spaces created by removing the parts of the insulating layers 102, via the openings 181A, and moreover, the insulating layer 181 and the insulating layer 181O are formed in the openings 181A. This step is performed by the likes of RIE, CVD, and wet etching, for example.

### Third Embodiment

### Configuration

FIG. 33 is a schematic plan view showing a configuration of a part of a semiconductor memory device according to a third embodiment.

Note that in the following description, configurations similar to in the first embodiment will be assigned with the same symbols as in the first embodiment, and descriptions thereof omitted.

The semiconductor memory device according to the present embodiment is basically configured similarly to the semiconductor memory device according to the first embodiment. However, in the semiconductor memory device according to the present embodiment (FIG. 33), the local block connecting line LBIY and the contact electrode CC do not have the local block select transistor SWY1 (FIG. 1) provided therebetween. In the semiconductor memory device according to the present embodiment (FIG. 33), the local block select transistor SWX1 is provided between the plurality of memory strings MS and the contact electrode CC.

### Advantages

In the present embodiment, a local block select transistor SWX1 connected to a selected memory block region R_{BLK} is set to an ON state, and a local block select transistor SWX1 connected to an unselected memory block region R_{BLK} is set to an OFF state. Such a configuration makes it possible to reduce a portion of parasitic capacitance originating from the unselected memory block region R_{BLK}, and improve speed of operation.

### Fourth Embodiment

### Configuration

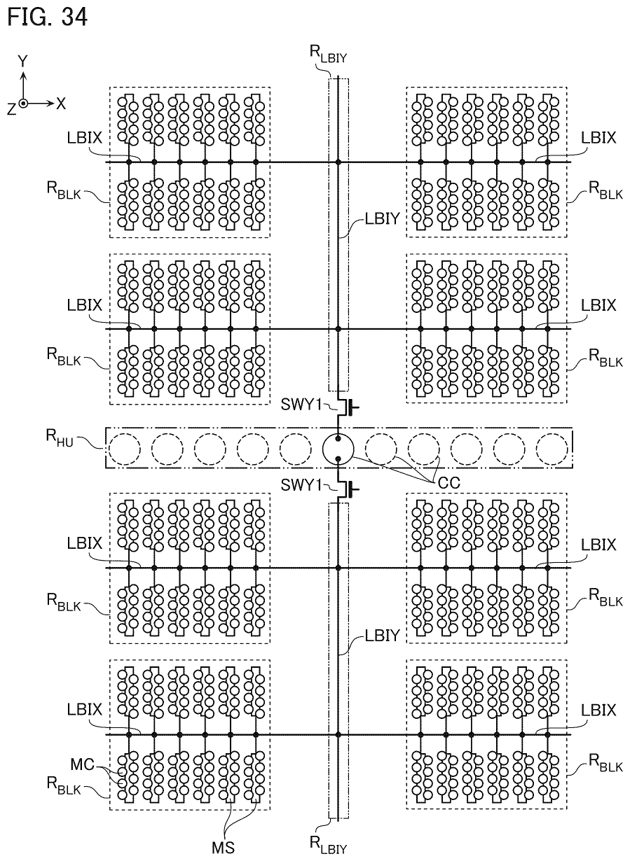

FIG. 34 is a schematic plan view showing a configuration of a part of a semiconductor memory device according to a fourth embodiment.

Note that in the following description, configurations similar to in the first embodiment will be assigned with the same symbols as in the first embodiment, and descriptions thereof omitted.

The semiconductor memory device according to the present embodiment is basically configured similarly to the semiconductor memory device according to the first embodiment. However, in the semiconductor memory device according to the present embodiment (FIG. 34), the local block connecting line LBIX and the local block connecting line LBIY do not have the local block select transistor SWX1 (FIG. 1) provided therebetween. In the semiconductor memory device according to the present embodiment (FIG. 34), the local block select transistor SWY1 is provided between the contact electrode CC and the plurality of memory block regions R_{BLK}.

### Advantages

In the present embodiment, a local block select transistor SWY1 connected to a selected memory block region R_{BLK} is set to an ON state, and a local block select transistor SWY1 all of the plurality of memory block regions R_{BLK} connected to which are unselected, is set to an OFF state. Such a configuration enables a portion of parasitic capacitance originating from the memory block regions R_{BLK} and the local block connecting line LBIY connected to a local block select transistor SWY1 in an OFF state, to be reduced, and makes it possible for speed of operation to be improved.

### Fifth Embodiment

### Configuration

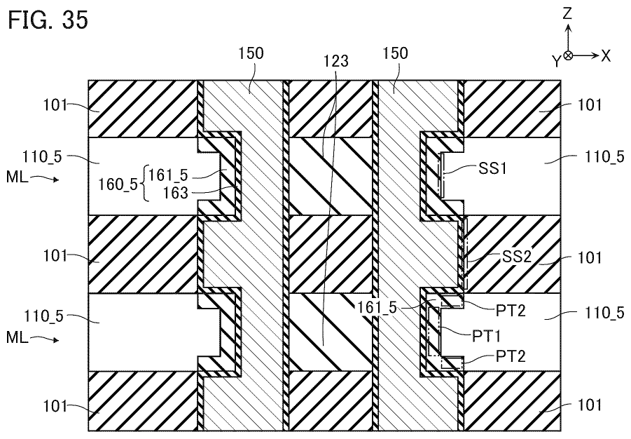

FIG. 35 is a schematic cross-sectional view showing a configuration of a part of a semiconductor memory device according to a fifth embodiment. FIG. 35 is a cross-sectional view of a portion corresponding to FIG. 7, and shows a cross section of the select transistor SG.

Note that in the following description, configurations similar to in the first embodiment will be assigned with the same symbols as in the first embodiment, and descriptions thereof omitted.

The semiconductor memory device according to the present embodiment is basically configured similarly to the semiconductor memory device according to the first embodiment (FIG. 7). However, the semiconductor memory device according to the present embodiment (FIG. 35) comprises a semiconductor layer 110_5 instead of the semiconductor layer 110, and comprises a gate insulating layer 160_5 instead of the gate insulating layer 160.

The semiconductor layer 110_5 is basically configured similarly to the semiconductor layer 110 (FIG. 7). However, as shown in FIG. 35, for example, the semiconductor layer 110_5 comprises a portion protruding to a conductive layer 150 side, in its side surface on a side facing the conductive layer 150. A surface being a side surface on the conductive layer 150 side and most closely facing the conductive layer 150, of the semiconductor layer 110_5 will be referred to as a surface SS1. Moreover, a side surface on the conductive layer 150 side, of the insulating layer 101 will be referred to as a surface SS2. The surface SS1 is disposed further to the conductive layer 150 side than is the surface SS2.

The gate insulating layer 160_5 is basically configured similarly to the gate insulating layer 160 (FIG. 7). However, the gate insulating layer 160_5 comprises an insulating layer 161_5 instead of the insulating layer 161.

The insulating layer 161_5 is basically configured similarly to the insulating layer 161. However, the insulating layer 161_5 is provided on a side surface in the X-direction on the conductive layer 150 side of the semiconductor layer 110_5, and on a part of a side surface in the Z-direction of the semiconductor layer 110_5, for example. The insulating layer 161_5 includes: a portion PT1 covering at least a part of the side surface in the X-direction of the semiconductor layer 110_5; and a portion PT2 covering at least a part of the side surface in the Z-direction of the semiconductor layer 110_5.

Note that the semiconductor layer 110 included in the local block select transistors SWX1, SWY1 (FIGS. 8 and 11) may also comprise a portion protruding to a conductive layer 350, 450 side in its side surface on a side facing the conductive layer 350, 450, similarly to the semiconductor layer 110_5. In such a configuration, the insulating layer 361, 461 included in the local block select transistors SWX1, SWY1 may be provided on a side surface in the X-direction on a conductive layer 350, 450 side of the semiconductor layer 110, and on a part of a side surface in the Z-direction of the semiconductor layer 110, similarly to the insulating layer 161_5.

### Method of Manufacturing

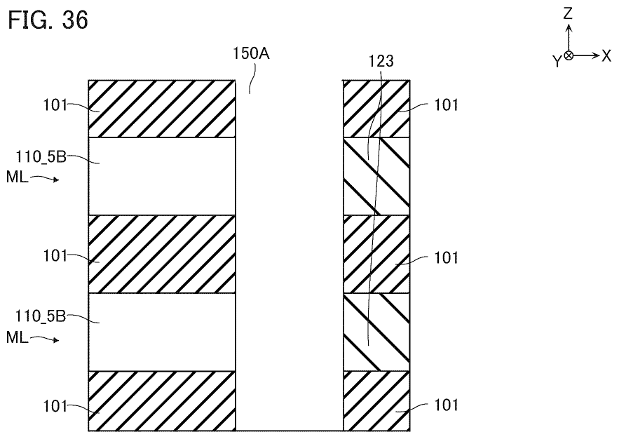

FIGS. 36 to 38 are schematic cross-sectional views for explaining a method of manufacturing the semiconductor memory device according to the fifth embodiment. FIGS. 36 to 38 correspond to a part of the configuration shown in FIG. 35.

Same method of manufacturing is basically similar to that of the first and second embodiments. However, in the method of manufacturing according to the fifth embodiment, the following steps described with reference to FIGS. 36 to 38 are executed instead of the steps corresponding to FIGS. 23 and 24.

In the step shown in FIG. 36, for example, the insulating layer 150O and the sacrifice layer 150B are removed to form the opening 150A, and then parts of the insulating layers 102 are removed via the opening 150A, and the semiconductor layers 110_5B formed in spaces created by removing the parts of the insulating layers 102, via the opening 150A. The semiconductor layer 110_5B includes a similar material to the semiconductor layer 110_5.

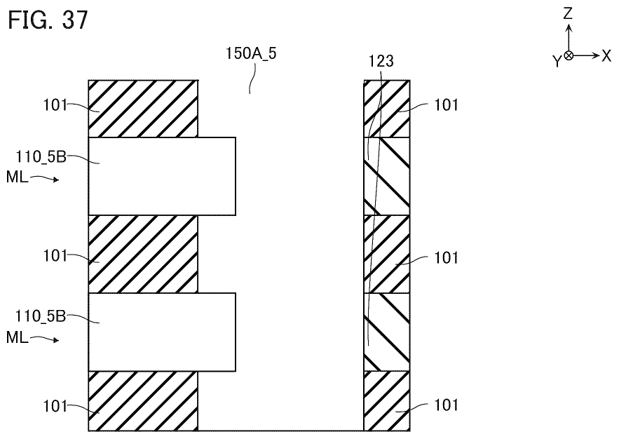

Next, in the step shown in FIG. 37, for example, parts on an opening 150A side of the insulating layers 101, 123 are removed via the opening 150A to form an opening 150A_5. A side surface in the X-direction and a part of a side surface in the Z-direction of the semiconductor layer 110_5B are exposed in the opening 150A_5. This step is performed by the likes of RIE and wet etching, for example.

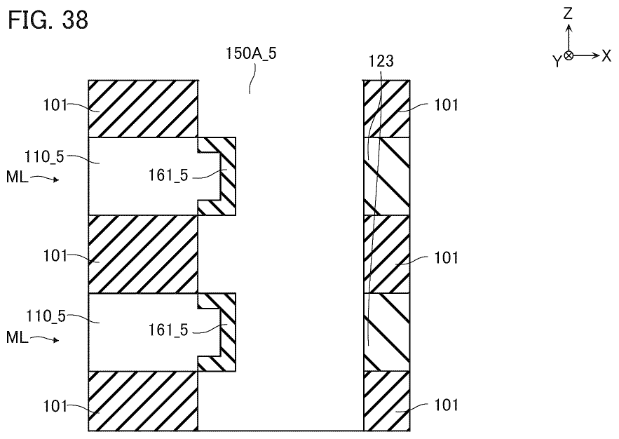

Next, in the step shown in FIG. 38, for example, the insulating layer 161_5 is formed on the side surface on an opening 150A_5 side of the semiconductor layer 110_5 and a part of the side surface in the Z-direction of the semiconductor layer 110_5. This step is performed by the likes of thermal oxidation, for example.

Next, the insulating layer 163 and the conductive layer 150 are sequentially formed in the opening 150A_5, and the structure described with reference to FIG. 35 is formed.

### Advantages

In a semiconductor memory device comprising layers arranged in the Z-direction, each of which comprises a plurality of semiconductor layers and a plurality of conductive layers, when the semiconductor layers arranged in the Z-direction each function as channel regions of transistors, sometimes, threshold voltage of the transistors will rise due to inter-channel interference in the Z-direction.

In the present embodiment, in the select transistor SG (FIG. 35) adopting the conductive layer 150 as its gate electrode and the local block select transistors SWX1, SWY1 adopting the conductive layers 350, 450 as their gate electrodes, a part of the insulating layer 101 provided between the memory layers ML is removed causing it to recede. Due to this kind of structure, a portion of the semiconductor layer 110_5 functioning as a channel region will be covered additionally from the Z-direction and have both of its sides in the Z-direction electrically shielded, by the conductive layers 150, 350, 450.

Such a configuration enables inter-channel interference in the Z-direction to be suppressed and a rise in transistor threshold voltage to be prevented in the select transistor SG and the local block select transistors SWX1, SWY1, and moreover makes it possible for operating current to be increased.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of memory block regions arranged in a first direction;
a hook-up region arranged in the first direction with respect to the plurality of memory block regions; and
a wiring region extending in the first direction and arranged with the plurality of memory block regions in a second direction intersecting the first direction, wherein the plurality of memory block regions each comprise:
a plurality of memory strings extending in the first direction and arranged in the second direction; and
a first wiring extending in the second direction and commonly connected to the plurality of memory strings,
the wiring region comprises a second wiring which extends in the first direction and is commonly connected to a plurality of the first wirings corresponding to the plurality of memory block regions,
the hook-up region comprises a contact electrode which extends in a third direction intersecting the first direction and the second direction, and is electrically connected to the second wiring, and
a first transistor is provided in a current path between the first wiring and the second wiring.

2. The semiconductor memory device according to claim 1, comprising
a plurality of memory layers arranged in the third direction, wherein
the plurality of memory layers each comprise the plurality of memory strings, the first wiring, the second wiring, and the first transistor, and
the hook-up region comprises a plurality of the contact electrodes correspondingly to the plurality of memory layers.

3. The semiconductor memory device according to claim 1, wherein
a second transistor is provided in a current path between the second wiring and the contact electrode.

4. The semiconductor memory device according to claim 1, wherein
a third transistor is provided, in parallel with the first transistor, in a current path between the first wiring and the second wiring,
the first transistor is an N-type transistor, and
the third transistor is a P-type transistor.

5. The semiconductor memory device according to claim 3, wherein
a fourth transistor is provided, in parallel with the second transistor, in a current path between the second wiring and the contact electrode,
the second transistor is an N-type transistor, and
the fourth transistor is a P-type transistor.

6. The semiconductor memory device according to claim 1, wherein
a gate electrode of the first transistor includes a plurality of first electrodes which extend in the third direction, and
the plurality of first electrodes are arranged in the first direction.

7. The semiconductor memory device according to claim 6, wherein
the plurality of memory strings each comprise:
a plurality of memory cells arranged in the first direction; and
a plurality of memory gate electrodes arranged in the first direction correspondingly to the plurality of memory cells arranged in the first direction, and
a pitch at which the plurality of first electrodes are arranged is equal to a pitch at which the plurality of memory gate electrodes are arranged.

8. The semiconductor memory device according to claim 1, wherein
the plurality of memory strings each comprise
a plurality of memory cells and at least one select transistor which are arranged in the first direction and are connected in series to the first wiring.

9. The semiconductor memory device according to claim 1, wherein
the plurality of memory strings each comprise
a first semiconductor layer extending in the first direction.

10. The semiconductor memory device according to claim 9, wherein
the plurality of memory strings each comprise a plurality of memory gate electrodes arranged in the first direction, and
between each of the plurality of memory gate electrodes and the first semiconductor layer, there are provided:
a first insulating layer and a second insulating layer; and
an electric charge accumulating layer which is provided between the first insulating layer and the second insulating layer.

11. The semiconductor memory device according to claim 9, wherein
the first semiconductor layer includes polycrystalline silicon (Si).

12. The semiconductor memory device according to claim 1, wherein
the first transistor comprises
a second semiconductor layer extending in the first direction.

13. The semiconductor memory device according to claim 12, wherein
the first transistor comprises:
a plurality of first electrodes which are provided on one side in the second direction with respect to the second semiconductor layer, and extend in the third direction; and
a second electrode which is provided on the other side in the second direction with respect to the second semiconductor layer, is electrically connected to the second semiconductor layer, and extends in the third direction.

14. A semiconductor memory device comprising:
a first memory layer and a second memory layer; and
an inter-layer insulating layer provided between the first memory layer and the second memory layer, wherein
the first memory layer and the second memory layer each includes:
a plurality of memory block regions arranged in a first direction; and
a wiring region extending in the first direction and arranged with the plurality of memory block regions in a second direction intersecting the first direction,
the first memory layer and the second memory layer are arranged in a third direction intersecting the first direction and the second direction,
the plurality of memory block regions each comprise:
a plurality of semiconductor portions extending in the first direction and arranged in the second direction; and
a first wiring extends in the second direction and commonly connected to the plurality of semiconductor portions,
the wiring region comprises a second wiring which extends in the first direction and is commonly connected to a plurality of the first wirings corresponding to the plurality of memory block regions,
there is provided:
a plurality of memory gate electrodes which are arranged in the first direction, extend in the third direction, and face a first semiconductor layer being one of the plurality of semiconductor portions, and the inter-layer insulating layer; and
a select gate electrode which is provided between the plurality of memory gate electrodes and the first wiring, extends in the third direction, and faces the first semiconductor layer and the inter-layer insulating layer, and
at least a part of a side surface facing the select gate electrode, of the first semiconductor layer is provided further to a select gate electrode side than is a side surface facing the select gate electrode, of the inter-layer insulating layer.

15. The semiconductor memory device according to claim 14, comprising
a gate insulating layer between the first semiconductor layer and the select gate electrode, wherein
the gate insulating layer comprises:
a first portion covering at least a part of a side surface in the second direction, of the first semiconductor layer; and
a second portion covering at least a part of a side surface in the third direction, of the first semiconductor layer.

16. The semiconductor memory device according to claim 14, wherein
the first memory layer and the second memory layer each comprise
a first transistor in a current path between the first wiring and the second wiring.

17. The semiconductor memory device according to claim 16, wherein
the first transistor comprises a second semiconductor layer,
the first transistor is provided with a first electrode extending in the third direction and facing the second semiconductor layer and the inter-layer insulating layer, and
a side surface facing the first electrode, of the second semiconductor layer is provided further to a first electrode side than is a side surface facing the first electrode, of the inter-layer insulating layer.

18. The semiconductor memory device according to claim 17, wherein
the first transistor comprises:
a plurality of the first electrodes which are provided on one side in the second direction with respect to the second semiconductor layer, and extend in the third direction; and
a second electrode which is provided on the other side in the second direction with respect to the second semiconductor layer, is electrically connected to the second semiconductor layer, and extends in the third direction.

19. The semiconductor memory device according to claim 14, wherein
between each of the plurality of memory gate electrodes and the first semiconductor layer, there are provided:
a first insulating layer and a second insulating layer; and
an electric charge accumulating layer which is provided between the first insulating layer and the second insulating layer.
